(19) United States
(12) Patent Application Publication
(10) Pub. No.: US 2026/0182026 A1
(43) Pub. Date: Jun. 25, 2026

(54) SEMICONDUCTOR DEVICE

(71) Applicant: Samsung Electronics Co., Ltd., Suwon-si (KR)

(72) Inventors: Yongyoung PARK, Suwon-si (KR); Kiyeon YANG, Suwon-si (KR); Jongbong PARK, Suwon-si (KR); Young Jae KANG, Suwon-si (KR)

(73) Assignee: Samsung Electronics Co., Ltd., Suwon-si (KR)

(21) Appl. No.: 19/179,323

(22) Filed: Apr. 15, 2025

(30) Foreign Application Priority Data
Oct. 8, 2024 (KR) 10-2024-0136804

(51) Int. Cl. H10D 86/40; H10D 30/67

(52) U.S. Cl. CPC H10D 86/423; H10D 30/6756; H10D 30/6757

(57) ABSTRACT

Provided is a semiconductor device including a substrate, a source/drain region on the substrate, a channel layer connected to the source/drain region, a barrier film on the source/drain region, and a gate electrode on the barrier film, wherein the channel layer includes a p-type oxide semiconductor material that contains tin (Sn) and tellurium (Te) and has an oxygen deficient composition.

### CROSS-REFERENCE TO RELATED APPLICATIONS

This application claims the benefit of Korean Patent Application No. 10-2024-0136804, filed on Oct. 8, 2024, in the Korean Intellectual Property Office, the disclosure of which is incorporated herein by reference in its entirety.

### BACKGROUND

### 1. Field

Example embodiments relate to semiconductor devices.

### 2. Description of the Related Art

In order to implement a complementary metal-oxide-semiconductor (CMOS) logic circuit, a p-type semiconductor material may be advantageous. Tin telluride (SnTe), known as a p-type semiconductor material, has good hall mobility characteristics, but has low resistivity. Thus, transistors employing SnTe exhibit a low on/off ratio.

Oxide semiconductor materials generally have a large band gap compared to silicon-based semiconductors. The oxide semiconductor materials with a larger band gap have a lower leakage current.

### SUMMARY

Some example embodiments of the present disclosure provide semiconductor devices that secure relatively good hole mobility characteristics and a relatively high on/off ratio to reduce or minimize leakage current.

Example embodiments of the present disclosure are not limited to the above-mentioned example embodiments. That is, other example embodiments that are not mentioned may be obviously understood by those skilled in the art from the following description.

According to an example embodiment, a semiconductor device includes a substrate, a source/drain region on the substrate, a channel layer connected to the source/drain region, a barrier film on the source/drain region, and a gate electrode on the barrier film, wherein the channel layer contains a p-type oxide semiconductor material, the p-type oxide semiconductor material containing tin (Sn) and tellurium (Te) and having an oxygen deficient composition.

According to an example embodiment, a semiconductor device includes a substrate, a source/drain region on the substrate, a channel layer connected to the source/drain region, a barrier film on the source/drain region, and a gate electrode on the barrier film, where the channel layer includes an oxide film, and the oxide film contains a p-type oxide semiconductor material, the p-type oxide semiconductor material containing tin (Sn) and tellurium (Te) and having an oxygen deficient composition.

According to an example embodiment, a semiconductor device includes a substrate, a source/drain region on the substrate, a channel layer connected to the source/drain region, a barrier film on the source/drain region and a gate electrode on the barrier film, wherein the channel layer includes an oxide film, the oxide film contains a p-type oxide semiconductor material in an amorphous state, the p-type oxide semiconductor material having an oxygen deficient composition, the p-type oxide semiconductor material being SnₓTe_{y}O_{z}, where 0.8≤x≤1.2, 0.8≤y≤1.2, z/(x+y)<1.5, and 0.8<x/y<1.2, the p-type oxide semiconductor material having a band gap of 0.5 electronvolt (eV) or more.

Detailed contents of other example embodiments are described in a detailed description and are illustrated in the drawings.

According to semiconductor devices of example embodiments of the present disclosure, it is possible to secure the relatively good hole mobility characteristics and the relatively high on/off ratio to reduce or minimize the leakage current.

The effects of the present disclosure are not limited to the above-mentioned effects, and other effects that are not mentioned may be obviously understood by those skilled in the art from the following description.

### BRIEF DESCRIPTION OF THE FIGURES

The drawings illustrated in the present disclosure are according to some example embodiments, and a ratio of a width, depth, or height (or thickness) of each component is for describing the example embodiments of the present disclosure in detail, and these ratios may be different from the actual ones. In addition, each component illustrated in the drawings may be exaggerated in order to describe the example embodiments of the present disclosure in detail. In addition, each axis in coordinate systems illustrated in the drawings may be perpendicular to each other, and a direction pointed by an arrow may be a +direction, and a direction (direction rotated by) 180° opposite to the direction pointed by an arrow may be a −direction.

FIG. 1 is a plan view illustrating at least a portion of a semiconductor device according to an example embodiment of the present disclosure.

FIGS. 2 to 7 are plan views illustrating at least a portion of a channel layer according to some example embodiments of the present disclosure.

FIG. 8 is a diagram illustrating a density of states (DOS) measured through simulation according to density function theory for a p-type oxide semiconductor material according to an example embodiment of the present disclosure.

### DETAILED DESCRIPTION

Prior to the detailed description of the present disclosure, it should be noted that terms or words used in this specification and claims may not be interpreted as limited to their ordinary or dictionary meanings. In addition, the terms or words may be interpreted to have meanings and concepts that conform to the technical idea(s) of the present disclosure based on the principle that the inventor may appropriately define the concept(s) of terms to explain his or her own disclosure. The example embodiments described in this specification and the configurations illustrated in the drawings are merely some example embodiments of the present disclosure and may not represent all of the technical ideas of the present disclosure. Accordingly, there may be various equivalents and modified examples that may replace the example embodiments at the time of filing of the present disclosure.

The same reference numbers or symbols described in each drawing attached to this specification may indicate parts or components that perform substantially the same function. For the convenience of description and understanding, the same reference numbers or symbols may be used in different example embodiments. In other words, even if components having the same reference numbers are illustrated in multiple drawings, all the multiple drawings may not mean an example embodiment.

When a component is described herein as being “directly above” or “adjacent to” or “in contact with” another component, it may be understood that the component is directly contact or connected to the other component, and that there is no other component between these components.

In addition, when a component is described herein as being “above” or “on” another component, it may be understood that the component exists above in a vertical direction. These components may be in direct contact or connected with each other, but it may be understood that another component exists between these components. The same applies when a component is described herein as being “above” another component.

In addition, when a component is described herein as being “below” another component, it may be understood that the component exists below in a vertical direction. These components may be in direct contact or connected with each other, but it may be understood that another component exists between these components. The same applies when a component is described herein as being “below” another component.

Other similar expressions that describe the positional relationship between the components may be interpreted in the same manner as above.

In the following description, singular forms are intended to include plural forms unless the context clearly indicates otherwise. It should be further understood that the terms such as “include” or “configure” specify the presence of features, numerals, steps, operations, components, parts mentioned in the present specification, or combinations thereof, but do not preclude the presence or addition of one or more other features, numerals, steps, operations, components, parts, or combinations thereof.

In addition, in the following description, the terms such as “upper side,” “upper surface,” “lower side,” “lower surface,” “side surface,” “front surface,” and “rear surface” are expressed based on directions illustrated in the drawings, and may be differently expressed when directions of corresponding targets change.

In addition, in the specification and the claims, terms including ordinal numbers such as “first”, “second” and the like may be used to distinguish between components. These ordinal numbers may be used to distinguish the same or similar components from each other, and the meaning of the terms should not be restrictively construed by the use of these ordinal numbers. As an example, components combined with these ordinal numbers should not be limited in order of use or arrangement by the ordinal numbers. If desired, the respectively ordinal numbers may be interchangeably used.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

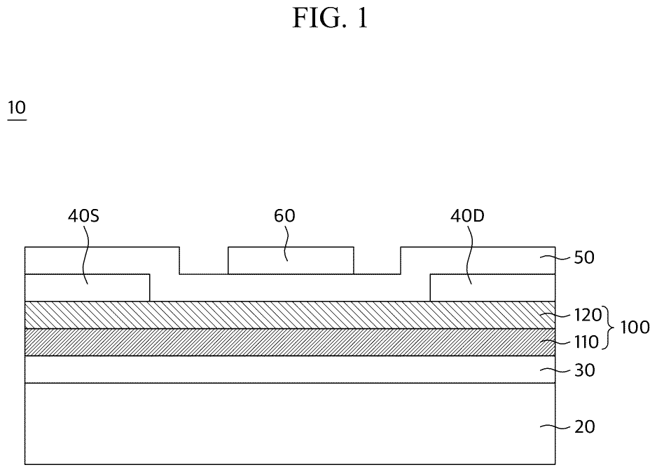

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. FIG. 1 is a plan view illustrating at least a portion of a semiconductor device 10 according to an example embodiment of the present disclosure. In an example, the semiconductor device 10 may include a substrate 20, source/drain regions 40S and 40D, a channel layer 100, a barrier film 50, and a gate electrode 60.

In an example, the semiconductor device 10 may be applied to a semiconductor field, a display field, or a solar cell field. In an example, the semiconductor device 10 may be one selected from the group consisting of a system large scale integration (LSI), a flash memory, a dynamic random access memory (DRAM), a static random access memory (SRAM), an electrically erasable programmable read-only memory (EEPROM), a phase-change random access memory (PRAM), a magnetic random access memory (MRAM), a ferroelectrics random access memory (FeRAM), and a resistive random access memory (RRAM). In an example, the semiconductor device 10 may include various types of a plurality of individual devices. The plurality of individual devices may include, but are not particularly limited to, a metal-oxide-semiconductor field effect transistor (MOSFET) such as a complementary metal-oxide-semiconductor (CMOS) transistor, an image sensor such as a CMOS imaging sensor (CIS), an active device, or a passive device, as long as the plurality of individual devices are used in the art. In an example, the semiconductor device 10 may include a thin film transistor (TFT), and in an example, a structure of the thin film transistor may refer to FIG. 1.

In an example, the substrate 20 may be, but is not limited to, a silicon semiconductor substrate, a plastic substrate, a glass substrate, a compound semiconductor substrate, a ceramic substrate, or a silicon on insulator (SOI) substrate. In an example, although not separately illustrated, the substrate 20 may include, but is not limited to, a peripheral circuit that is configured to select and/or control an impurity region or a memory cell due to doping.

In an example, the semiconductor device 10 may include an insulating film 30 on the substrate 20. The insulating film 30 may contain an insulating material. In the present specification, the insulating material may contain, but is not limited to, one or more selected from the group consisting of silicon oxide, silicon nitride, silicon oxynitride, a low-k material, and a high-k material. In the present specification, the low-k material may have a permittivity less than 3.9 and examples of the low-k material may contain, but is not limited to, one or more from the group consisting of fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), silicon low-k (SiLK), amorphous fluorinated carbon, silica aerogels, silica xerogels, and mesoporous silica. In the present specification, the high-k material may have a permittivity of 3.9 or higher, and examples of the high-k material may include, but is not limited to, one or more from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

In an example, the source/drain regions 40S and 40D may be disposed on the substrate 20. The source/drain regions 40S and 40D may be plural, and each of the source/drain regions 40S and 40D may be spaced apart from each other. In some cases, the source/drain regions 40S and 40D may be divided into the source region 40S and the drain region 40D, but are not limited thereto.

In an example, the source/drain regions 40S and 40D may include an impurity, and the type of impurities may vary depending on a conductivity type. For example, the n-type may include an n-type dopant, which is an impurity containing at least one of phosphorus (P), arsenic (As), antimony (Sb), or bismuth (Bi). In addition, for example, the p-type may contain a p-type dopant, which is an impurity containing at least one of boron (B) or gallium (Ga). At least some of the plurality of source/drain regions 40S and 40D may be n-type or p-type. Some of the plurality of source/drain regions 40S and 40D may be n-type and others may be p-type.

In an example, the source/drain regions 40S and 40D may contain one or more selected from the group consisting of silicon, metal, metal nitride, metal silicide, and metal oxide. In the present specification, the metal may contain one or more selected from the group consisting of aluminum (Al), copper (Cu), titanium (Ti), tantalum (Ta), rubidium (Ru), tungsten (W), molybdenum (Mo), platinum (Pt), nickel (Ni), tin (Sn), lead (Pb), and cobalt (Co). In the present specification, the metal nitride may contain one or more selected from the group consisting of titanium nitride (TiN), titanium aluminum nitride (TiAIN), tantalum silicon nitride (TaSiN), and rubidium titanium nitride (RuTiN). In the present specification, the metal silicide may contain one or more selected from the group consisting of titanium silicide (TiSi), tantalum silicide (TaSi), nickel silicide (NiSi), and cobalt silicide (CoSi). In the present specification, the metal oxide may contain one or more selected from the group consisting of iridium oxide (IrOx) and rubidium oxide (RuOx).

In an example, the barrier film 50 may be disposed on the source/drain regions 40S and 40D. In an example, the barrier film 50 may include one or more selected from the group consisting of, but not limited to, metal oxide, silicon oxide, silicon nitride, silicon oxynitride, a low-k material, and a high-k material. In an example, examples of the metal oxide may contain one or more selected from the group consisting of aluminum oxide (AlO) and tin oxide (SnO).

In an example, the gate electrode 60 may be disposed on the barrier film 50. The gate electrode 60 may not contact at least a portion of the source/drain regions 40S and 40D. In an example, the gate electrode 60 may be electrically connected to a word line. In an example, the gate electrode 60 may include the conductive material described above. In the present specification, the conductive material may contain one or more selected from the group consisting of doped polysilicon, metal, metal nitride, metal silicide, and metal oxide.

In an example, the channel layer 100 may be connected to the source/drain regions 40S and 40D. The channel layer 100 may contain tin (Sn) and tellurium (Te). Tin telluride (SnTe) has relatively good hole mobility characteristics, but has low resistivity. Thus, a transistor made of the tin telluride may have a low on/off ratio. The channel layer 100 may contain a p-type oxide semiconductor material that contains tin (Sn) and tellurium (Te) and has an oxygen deficient composition. In the present specification, the term “oxygen deficiency” may refer to a mismatch state in which a matching ratio of an element bonded to oxygen and oxygen in an oxide is not satisfied. Specifically, the mismatch state may refer to a state in which an octet rule or an 18-electron rule is not satisfied. For example, when a matching ratio of an element A bonded to oxygen and oxygen (O) in an oxide is A:O=1:2, the oxide having the oxygen deficient composition may satisfy AO₂₋ₓ (0<x<2). Through this, the semiconductor device 10 may increase resistivity and improve an on/off ratio.

In an example, the p-type oxide semiconductor material may be SnₓTe_{y}O_{z}, where, 0.8≤x≤1.2, 0.8≤y≤1.2, and z/(x+y)<1.5.

In an example, where, 0.9≤x≤1.1 or 0.95≤x≤1.05 may be satisfied.

In an example, where, 0.9≤y≤1.1 or 0.95≤y≤1.05 may be satisfied.

In an example, where, z/(x+y)<1.4, z/(x+y)<1.3, z/(x+y)<1.2, z/(x+y)<1.1, or z/(x+y)<1 may be satisfied.

In an example, where, 0.8<x/y<1.2, 0.9<x/y<1.1 or 0.95<x/y<1.05 may be satisfied.

As described above, the p-type oxide semiconductor material may contain tin (Sn) and tellurium (Te), and the ratios x, y, and z between tin (Sn), tellurium (Te), and oxygen (O) may be appropriately controlled to exhibit p-type semiconductor characteristics.

In an example, the p-type oxide semiconductor material may be in a mismatch state in which the matching ratio between tin (Sn) and tellurium (Te) and oxygen element (O) is not satisfied. In this way, the p-type oxide semiconductor material may have the oxygen deficient composition.

In an example, the p-type oxide semiconductor material may have a band gap of about 0.5 electronvolt (eV) or more, about 0.6 eV or more, about 0.7 eV or more, about 0.8 eV or more, about 0.9 eV or more, about 1 eV or more, about 1.1 eV or more, exceeding about 1.1 eV, about 1.15 eV or more, or about 1.2 eV or more. In an example, when the band gap of the p-type oxide semiconductor material is within the above-described range, a leakage current may be reduced or minimized.

In an example, the p-type oxide semiconductor material may be in an amorphous state. Through this, the semiconductor device 10 may increase resistivity and/or improve an on/off ratio.

In an example, the p-type oxide semiconductor material may satisfy one or more of the following properties according to a hall measurement method. In the present specification, the properties of the p-type oxide semiconductor material may be measured by the hall measurement method in a state where it is formed as a thin film. For example, the properties of the p-type oxide semiconductor material may be measured by a hole measurement method by connecting indium (In) electrodes to four vertices of a square sample having a width of about 1 centimeter (cm) and a length of about 1 cm. In an example, the p-type oxide semiconductor material may have a hall coefficient (RHs) of about 0.03 square meters per coulomb (m²/C) or more to about 0.04 m²/C or less, about 0.032 m²/C or more to about 0.038 m²/C or less, about 0.033 m²/C or more to about 0.036 m²/C or less, or about 0.034 m²/C or more to about 0.035 m²/C or less, which is measured by the hall measurement method described above.

In an example, the p-type oxide semiconductor material may have a bulk resistance R of about 0.0002 ohm centimeters (Ω·cm) or more to about 0.0003 Ω·cm or less, about 0.00021 Ω·cm or more to about 0.00028 Ω·cm or less, or about 0.00022 Ω·cm or more to about 0.00025 Ω·cm or less, which is measured by the hall measurement method described above.

In an example, the p-type oxide semiconductor material may have a mobility of about 7 square centimeters per volt-second (cm²/V·s) or more to about 8 cm²/V·s or less, about 7.2 cm²/V·s or more to about 7.8 cm²/V·s or less, about 7.4 cm²/V·s or more to about 7.75 cm²/V·s or less, or about 7.5 cm²/V's or more to about 7.7 cm²/V·s or less, which is measured by the hall measurement method described above.

In an example, the p-type oxide semiconductor material may have a hall bulk concentration (Nb) of about 3×10²¹/cubic centimeters (cm³) or more to about 4×10²¹/cm³ or less, about 3.2×10²¹/cm³ or more to about 3.8×10²¹/cm³ or less, about 3.4×10²¹/cm³ or more to about 3.7×10²¹/cm³ or less, or about 3.5×10²¹/cm³ or more to about 3.6×10²¹/cm³ or less, which is measured by the hall measurement method described above.

In an example, the p-type oxide semiconductor material may have a hall sheet concentration (Ns) of about 1.5×10¹⁶/cm² or more to about 2.1×10¹⁶/cm² or less, about 1.6×10¹⁶/cm² or more to about 2.0×10¹⁶/cm² or less, about 1.7×10¹⁶/cm² or more to about 1.9×10¹⁶/cm² or less, or about 1.8×10¹⁶/cm² or more to about 1.85×10¹⁶/cm² or less, which is measured by the hall measurement method described above.

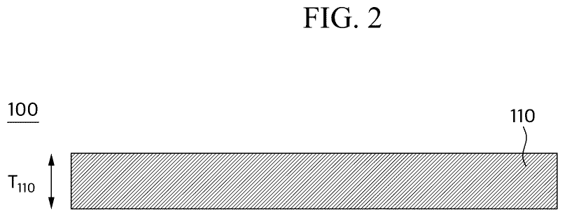

FIGS. 2 to 7 are plan views illustrating at least a portion of the channel layer 100 according to an example embodiment of the present disclosure. In an example, the channel layer 100 may include an oxide film 110. In an example, the oxide film 110 may contain the p-type oxide semiconductor material that contains tin (Sn) and tellurium (Te) and has the oxygen deficient composition. The P-type oxide semiconductor material may refer to the above-described contents.

In an example, the oxide film 110 may be a thin film. In an example, a thickness T110 of the oxide film 110 may be about 100 nm or less, about 90 nm or less, about 80 nm or less, about 70 nm or less, about 60 nm or less, or about 50 nm or less. The oxide film 110 may be performed through deposition, and the deposition may be performed through chemical vapor deposition (CVD), physical vapor deposition (PVD), or atomic layer deposition (ALD). In an example, the oxide film 110 may be formed through reactive sputtering after injecting oxygen gas (O₂) into a chamber using a non-oxide as a target material.

Referring to FIG. 2, in an example, the channel layer 100 may be formed of or include the oxide film 110.

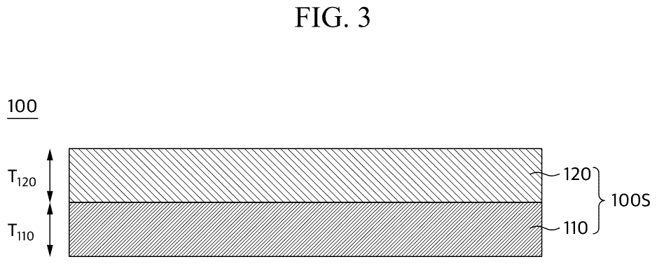

Referring to FIG. 3, in an example, the channel layer 100 may include a non-oxide film 120 made of or including the p-type non-oxide semiconductor material. In one example, the non-oxide film 120 may be disposed on the oxide film 110. In an example, the semiconductor layer 100 may increase the resistivity of the semiconductor device 10 by combining the oxide film 110 and the non-oxide film 120, improve the on/off ratio, and/or improve the hall mobility through the non-oxide film 120.

In an example, the channel layer 100 may include a structure 100S in which the oxide film 110 and the non-oxide film 120 are stacked adjacent to each other.

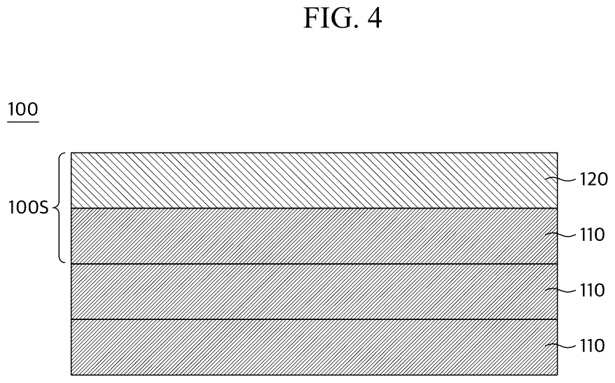

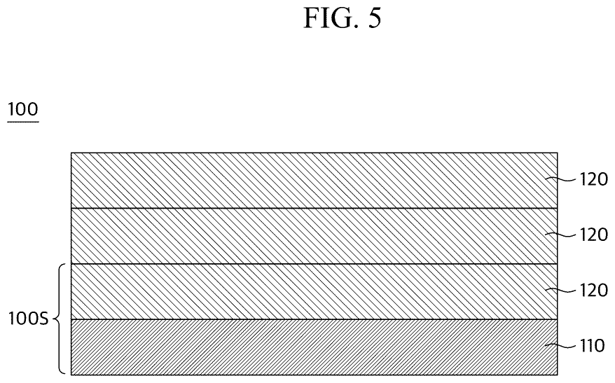

Referring to FIG. 4, in an example, the channel layer 100 may include the plurality of oxide films 110 and one or more non-oxide films 120, and may include the structure 100S in which the oxide films 110 and the non-oxide films 120 are stacked adjacent to each other. Referring to FIG. 5, in an example, the channel layer 100 may include one or more oxide films 110 and the plurality of non-oxide films 120, and may include the structure 100S in which the oxide films 110 and the non-oxide films 120 are stacked adjacent to each other.

In an example, the channel layer 100 may include the plurality of oxide films 110 and the plurality of non-oxide films 120. Here, the channel layer 100 may include the structure in which the oxide films 110 and the non-oxide films 120 are alternately stacked.

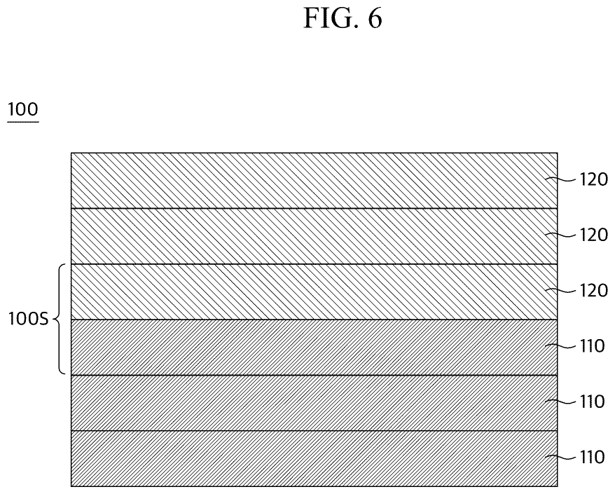

Referring to FIG. 6, in an example, the channel layer 100 may include the plurality of oxide films 110 and the plurality of non-oxide films 120, and may include the structure 100S in which the oxide films 110 and the non-oxide films 120 are stacked adjacent to each other. In particular, a plurality of non-oxide films 120 may be provided on the plurality of oxide films 110.

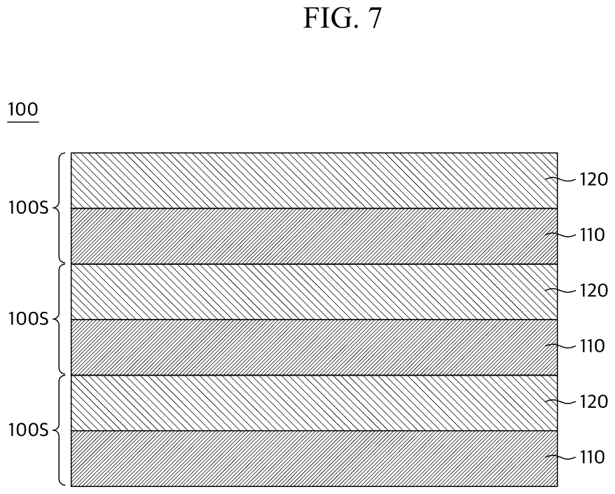

Referring to FIG. 7, in an example, the channel layer 100 may include the plurality of oxide films 110 and the plurality of non-oxide films 120, and may have the structure in which the oxide films 110 and the non-oxide films 120 are alternately stacked. Here, the channel layer 100 may include the plurality of structures 100S in each of which the oxide film 110 and the non-oxide film 120 may be stacked adjacent to each other.

According to an example embodiment, when manufacturing the channel layer 100, the channel layer 100 may be formed by depositing the oxide film 110 and then depositing the non-oxide film 120. According to an example embodiment, when manufacturing the channel layer 100, the channel layer 100 may be formed by depositing the non-oxide film 120 and then depositing the oxide film 110. According to an example embodiment, when manufacturing the channel layer 100, the channel layer 100 may be formed by depositing the plurality of oxide films 110 and depositing one or more non-oxide films 120. According to an example embodiment, when manufacturing the channel layer 100, the channel layer 100 may be formed by depositing the plurality of non-oxide films 120 and depositing one or more oxide films 110.

In an example, a band gap B_{G2} of the p-type non-oxide semiconductor material included in the non-oxide film 120 may be smaller than a band gap B_{G1} of the p-type oxide semiconductor material included in the oxide film 110.

In an example, a ratio B_{G1}/B_{G2} of the band gap B_{G1} of the p-type oxide semiconductor material to the band gap B_{G2} of the p-type non-oxide semiconductor material may be about 3 or more, about 3.5 or more, about 4 or more, about 4.5 or more, about 5 or more, about 5.5 or more, about 6 or more, or about 6.5 or more. When the ratio B_{G1}/B_{G2} of the band gaps described above satisfies the above-described range, the semiconductor device 10 may increase the resistivity, improve the on/off ratio, and/or improve the hall mobility.

In an example, the p-type non-oxide semiconductor material may contain, for example, a group IV element and a group VI element. In the present specification, the group IV element may contain one or more selected from the group consisting of group 4 elements and group 14 elements of the periodic table. Examples of the group IV element may contain one or more selected from the group consisting of silicon (Si), germanium (Ge), tin (Sn), titanium (Ti), and zirconium (Zr). In the present specification, the group VI element may contain one or more selected from the group consisting of group 6 elements and group 16 elements of the periodic table. Examples of the group IV element may include at least one selected from the group consisting of, for example, oxygen (O), sulfur(S), selenium (Se), tellurium (Te), chromium (Cr), molybdenum (Mo), and tungsten (W).

In an example, the p-type non-oxide semiconductor material may contain tin (Sn) and tellurium (Te). The p-type non-oxide semiconductor material may contain tin telluride (SnTe).

In an example, because the p-type non-oxide semiconductor material contains tin telluride (SnTe), the oxide film 110 and the non-oxide film 120 may be more easily formed. In an example, when forming the oxide film 110 through reactive sputtering, because the target materials of the oxide film 110 and the non-oxide film 120 are the same as the tin telluride (SnTe), the oxide film 110 and the non-oxide film 120 may be formed without changing the target materials.

In an example, the thickness T110 of the oxide film 110 and a thickness T120 of the non-oxide film 120 are not particularly limited in consideration of the application field.

Hereinafter, some example embodiments of the present disclosure will be further described with reference to specific Examples. The specific examples are merely illustrative of the present disclosure and do not limit the scope of the appended claims. It will be apparent to those skilled in the art that various changes and modifications to the example embodiments are possible within the scope and technical idea of the present disclosure. In addition, it is natural that such variations and modifications fall within the scope of the appended claims.

### Example 1

A channel layer 100 composed of an oxide film 110 made of Sn_{41.95}Te_{40.59}O_{17.43} with an oxygen deficient composition was manufactured by reactive sputtering after injecting oxygen gas (O₂) into a chamber using tin telluride (SnTe) as a target material.

### Example 2

A channel layer 100 composed of an oxide film 110 made of Sn₂₀Te₂₀O₅₀ with an oxygen deficient composition was manufactured by reactive sputtering after injecting oxygen gas (O₂) into a chamber using tin telluride (SnTe) as a target material.

### Experimental Example 1

The properties of the channel layer 100 manufactured in Example 1 measured by the hall measurement method were shown in Table 1 below.

TABLE 1

| Hall | Bulk | | Hall bulk | Hall sheet |
|---|---|---|---|---|
| coefficient | resistance | Mobility | concentration | concentration |
| (m²/C) | (Ω · cm) | (cm²/V · s) | (/cm³) | (/cm²) |
| 0.0345 | 0.000227806 | 7.64 | 3.59 × 10²¹ | 1.811 × 10¹⁶ |

### Experimental Example 2

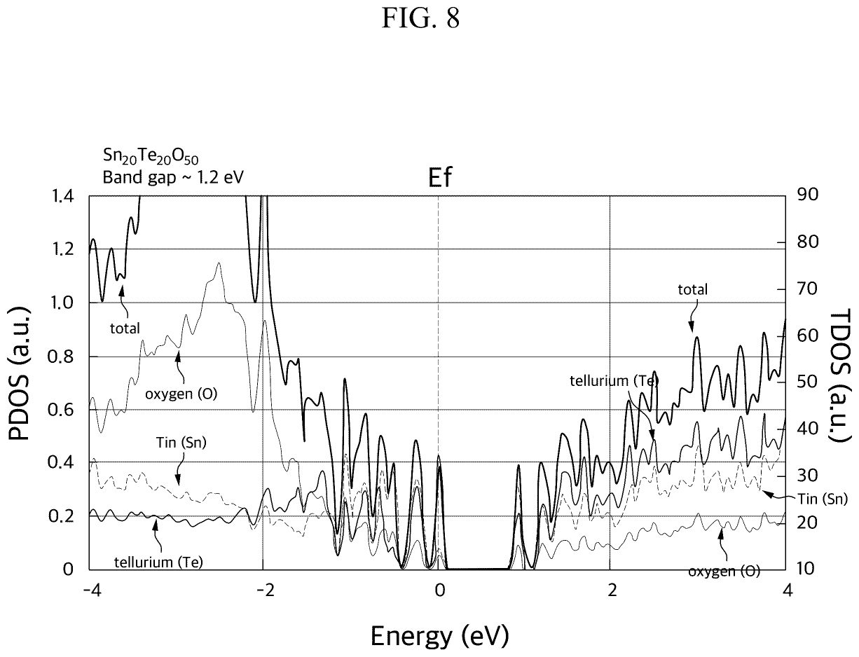

A density of state (DOS) of the channel layer 100 manufactured in Example 2 measured through simulation according to density function theory was measured and illustrated in FIG. 8. In FIG. 8, PDOS is a projected density of state (PDOS) and TDOS is a total density of state (TDOS).

Referring to FIG. 8, because a Fermi level (Ef) exists adjacent to a valence band, Sn₂₀Te₂₀O₅₀ with an oxygen deficient composition appeared as a p-type oxide semiconductor material, and the band gap was approximately 1.2 eV.

Some example embodiments of the present disclosure have been described hereinabove with reference to the accompanying drawings, but the present disclosure is not limited to the above-described example embodiments, and may be implemented in various different forms, and one of ordinary skill in the art to which the present disclosure pertains may understand that the present disclosure may be implemented in other specific forms without changing the technical spirit or essential features of the present disclosure. Therefore, it is to be understood that the example embodiments described above are illustrative rather than being restrictive in all aspects.

What is claimed is:

1. A semiconductor device, comprising:
a substrate;
a source/drain region on the substrate;
a channel layer connected to the source/drain region;
a barrier film on the source/drain region; and
a gate electrode on the barrier film,
wherein the channel layer contains a p-type oxide semiconductor material, the p-type semiconductor material containing tin (Sn) and tellurium (Te) and having an oxygen deficient composition.

2. The semiconductor device of claim 1, wherein the p-type oxide semiconductor material is SnₓTe_{y}O_{z}, where 0.8≤x≤1.2, 0.8≤y≤1.2, and z/(x+y)<1.5.

3. The semiconductor device of claim 2, wherein z/(x+y)<1.

4. The semiconductor device of claim 2, wherein 0.8<x/y<1.2.

5. The semiconductor device of claim 2, wherein 0.9≤x≤1.1, 0.9≤y≤1.1, and 0.9<x/y<1.1.

6. The semiconductor device of claim 1, wherein the p-type oxide semiconductor material has a band gap of 0.5 electronvolt (eV) or more.

7. The semiconductor device of claim 1, wherein the p-type oxide semiconductor material is in an amorphous state.

8. The semiconductor device of claim 1, wherein the p-type oxide semiconductor material satisfies one or more of the following properties according to a hall measurement method:
hall coefficient (RHs) of 0.03 square meters per coulomb (m²/C) or more to 0.04 m²/C or less;
bulk resistance (R) of 0.0002 ohm centimeters (Ω·cm) or more to 0.0003 Ω·cm or less;
Mobility of 7.0 square centimeters per volt-second (cm²/V·s) or more to 8.0 cm²/V·s or less;
hall bulk concentration (Nb) of 3.0×10²¹/cm³ or more to 4.0×10²¹/cm³ or less; and
hall sheet concentration (Ns) of 1.5×10¹⁶/cm² or more to 2.1×10¹⁶/cm² or less.

9. A semiconductor device, comprising:
a substrate;
a source/drain region on the substrate;
a channel layer connected to the source/drain region;
a barrier film on the source/drain region; and
a gate electrode on the barrier film,
wherein the channel layer includes an oxide film, and
the oxide film contains a p-type oxide semiconductor material, the p-type oxide semiconductor material containing tin (Sn) and tellurium (Te) and having an oxygen deficient composition.

10. The semiconductor device of claim 9, wherein a thickness of the oxide film is 100 nm or less.

11. The semiconductor device of claim 9, wherein the channel layer is formed of the oxide film.

12. The semiconductor device of claim 9, wherein the channel layer further includes a non-oxide film, the non-oxide film including a p-type non-oxide semiconductor material.

13. The semiconductor device of claim 12, wherein the p-type non-oxide semiconductor material contains a group IV element and a group VI element.

14. The semiconductor device of claim 12, wherein the p-type non-oxide semiconductor material contains tin (Sn) and tellurium (Te).

15. The semiconductor device of claim 12, wherein the channel layer includes at least one structure in which the oxide film and the non-oxide film are stacked adjacent to each other.

16. The semiconductor device of claim 12, wherein the channel layer includes a plurality of oxide films and a plurality of non-oxide films, the plurality of oxide films including the oxide film, the plurality of non-oxide films including the non-oxide film.

17. The semiconductor device of claim 16, wherein the channel layer includes a structure in which the oxide films and the non-oxide films are alternately stacked.

18. The semiconductor device of claim 12, wherein a band gap (B_{G2}) of the p-type non-oxide semiconductor material is smaller than a band gap (B_{G1}) of the p-type oxide semiconductor material.

19. The semiconductor device of claim 18, wherein a ratio (B_{G1}/B_{G2}) of the band gap (B_{G1}) of the p-type oxide semiconductor material to the band gap (B_{G2}) of the p-type non-oxide semiconductor material is 3 or more.

20. A semiconductor device, comprising:
a substrate;
a source/drain region on the substrate;
a channel layer connected to the source/drain region;
a barrier film on the source/drain region; and
a gate electrode on the barrier film,
wherein the channel layer includes an oxide film,
the oxide film contains a p-type oxide semiconductor material in an amorphous state, the P-type oxide semiconductor material having an oxygen deficient composition, the p-type oxide semiconductor material being SnₓTe_{y}O_{z}, where 0.8≤x≤1.2, 0.8≤y≤1.2, z/(x+y)<1.5, and 0.8<x/y<1.2, and
the p-type oxide semiconductor material has a band gap of 0.5 eV or more.
